(19) United States
(12) Patent Application Publication
(10) Pub. No.: US 2021/0043493 A1
(43) Pub. Date: Feb. 11, 2021

(54) POSITIONING TOOL

(71) Applicant: TRIXELL, Moirans (FR)

(72) Inventor: Yannick JANVIER, MOIRANS (FR)

(21) Appl. No.: 16/984,059

(22) Filed: Aug. 3, 2020

(30) Foreign Application Priority Data
Aug. 5, 2019 (FR) 1908964

(51) Int. Cl. H01L 21/683; H01L 21/677

(52) U.S. Cl. CPC H01L 21/6838; H01L 21/67745

(57) ABSTRACT

A positioning tool able to position a flat wafer on a flat support, includes a base; a gripping device connected to the base, defining a gripping plane; a bending device, having a first end connected to the base and a second end translationally movable along a first intersecting axis Z, which is preferably substantially perpendicular, through the gripping plane at a contact point. A positioning method is also provided.

### CROSS-REFERENCE TO RELATED APPLICATIONS

This application claims priority to foreign French patent application No. FR 1908964, filed on Aug. 5, 2019, the disclosure of which is incorporated by reference in its entirety.

### FIELD OF THE INVENTION

The invention relates to the technical field of the precise positioning of a potentially large flat wafer. More specifically, the invention is applicable to the fields requiring precise bonding (with precision possibly of less than 20 μm (micrometres)) of large semiconductor chips (possibly of up to several hundred millimetres), such as digital sensors, for example, for medical x-ray imaging using CMOS technology.

### BACKGROUND

During the assembly of a semiconductor chip, the chip is grasped and positioned at the desired location on the support covered with an adhesive film. The known picking and placing systems are denoted “pick and place” systems, indicating that the chip is picked and placed. Due to the small size of the chip (generally less than 50 mm×50 mm), this type of pick and place system is suitable and there should be no concern over positioning problems. In other words, the known pick and place systems of the prior art are only suitable for small chips.

When picking and placing a large chip, it is impossible, with the pick and place systems of the prior art, to implement plane-to-plane picking and placing. Indeed, in the phase whereby the chip approaches its intended support, a microscopic effect is observed: an edge or a corner of the chip touches part of the adhesive film covering the support, or the chip even slides when it comes into contact with the adhesive film. This results in the chip being offset relative to its desired position on the support.

Another problem that occurs due to the large dimensions of a chip is the non-uniform bonding of the chip on its support. During the phase of bonding the chip on its support, i.e. between two substantially flat parallel surfaces, air bubbles can form in the adhesive film. For this reason, the altimetry specifications stipulating a separation tolerance along an axis Z between the surfaces of adjacent chips extending in a plane perpendicular to the axis Z cannot be followed.

The existing solutions are not satisfactory since they allow neither handling nor precise alignment of large chips. Furthermore, they do not guarantee the absence of bubbles at the interface between the adhesive film and the CMOS wafer.

In other words, the known existing solutions do not allow the risk of settling on an edge or a corner of the chip to be avoided, making it impossible to provide any control over the effects of spurious movements during the phase of bonding the large chip on its support.

### SUMMARY OF THE INVENTION

The aim of the invention is to overcome all or some of the aforementioned problems by proposing a tool allowing gripping and the operation of picking and placing and bonding a chip, even if it is large, on an adhesive film on a sensor, whilst guaranteeing precise positioning by reducing the effects of mechanical movements when contact is made with the adhesive film, as well as whilst maintaining the integrity of the sensor. The proposed tool avoids the risks of indenting the layers of the chip. Furthermore, it allows standard consumables to be used offering a wide selection of hardnesses and electrical features, so as to guarantee the dissipative aspect in order to avoid electrostatic discharges.

To this end, the subject of the invention is a positioning tool able to position a flat wafer on a flat support, characterized in that it comprises:

a. a base;

b. a gripping device connected to the base, defining a gripping plane;

c. a bending device, having a first end connected to the base and a second end translationally movable along a first intersecting axis Z, which is preferably substantially perpendicular, through the gripping plane at a contact point.

Advantageously, the bending device is a point contact.

In one embodiment, the gripping device comprises at least two suction cups, each having a first end connected to the base and a second end located in the gripping plane.

Advantageously, the bending device is positioned between the at least two suction cups.

Advantageously, the at least two suction cups are connected to a vacuum network.

Advantageously, the at least two suction cups comprise silicon.

The bending device can be a presser finger, a spring, a bellows suction cup, a pressure screw, or a ball joint.

The invention also relates to a method for positioning a flat wafer on a flat support, characterized in that it comprises the following steps:

a. gripping the flat wafer using a gripping device;

b. holding the flat wafer in a gripping plane;

c. bending the flat wafer through translational movement along a first intersecting axis Z, which is preferably substantially perpendicular, from a second end of a bending device through the gripping plane at a contact point so as to form a bending point for the flat wafer.

The method can comprise, after the step of bending the flat wafer, a step of bringing the bending point of the curved flat wafer into contact with the flat support.

The method can comprise, after the contact step, a step of releasing the flat wafer onto the flat support.

### BRIEF DESCRIPTION OF THE DRAWINGS

The invention will be better understood and further advantages will become apparent upon reading the detailed description of an embodiment, which is provided by way of an example and is illustrated in the accompanying drawing, in which:

FIG. 1 schematically shows a positioning tool according to the invention;

FIG. 2 schematically shows an embodiment of the positioning tool according to the invention;

FIG. 3 schematically shows the steps of the method for positioning a flat wafer on a flat support according to the invention;

FIG. 4 schematically shows the positioning tool according to the invention during the step of gripping the chip;

FIG. 5 schematically shows the positioning tool according to the invention during the step of bending the chip;

FIG. 6 schematically shows the positioning tool according to the invention after the step of bringing the chip into contact on its support.

For the sake of clarity, the scales are not adhered to throughout these figures. Furthermore, the same elements will use the same reference signs throughout the various figures.

### DETAILED DESCRIPTION

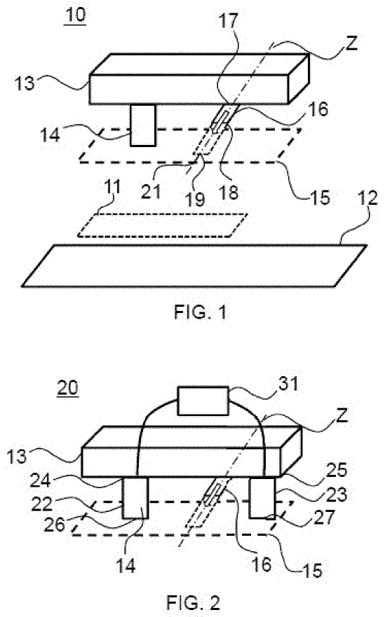

FIG. 1 schematically shows a positioning tool 10 according to the invention. The positioning tool 10 is able to position a flat wafer 11, for example, a chip, on a flat support 12, for example, a sensor. The positioning tool comprises a base 13, a gripping device 14 connected to the base 13, defining a gripping plane 15. The gripping plane 15 is substantially parallel to the flat support 12, so as to grip the flat wafer 11 and hold it in the gripping plane 15. The positioning tool 10 comprises a bending device 16, having a first end 17 connected to the base 13 and a second end 18 that is translationally movable along a first intersecting axis Z, which is preferably substantially perpendicular, through the gripping plane 15 at a contact point 19. It is to be noted that the gripping plane 15 is a virtual plane. The contact point 19 is a point of this gripping plane 15. It is the point where the second end 18 of the bending device 16 comes into contact with the gripping plane 15. When the positioning tool 10 grasps a flat wafer 11, the flat wafer 11 is held in the gripping plane 15. Subsequently, the second end 18 of the bending device 16 translationally moves along the axis Z and comes into contact with the flat wafer 11 at the contact point 19, or even comes into contact with the flat wafer 11 and simultaneously translationally moves through the effect of stress, as explained hereafter in the embodiment of FIG. 2. Through the translational movement of the second end 18 relative to the flat wafer 11, the flat wafer 11 bends at a bending point 191 (shown in FIG. 4). The bending device 16 is configured to define a bending point on the flat wafer 11, so as to bend the flat wafer 11 at this bending point 191.

The positioning tool 10 enables a controlled bend of the flat wafer 11 (for example, the chip) to be generated in order to be able to settle at a predetermined point of the flat wafer 11 (for example, at the centre of the chip) and to thus limit the effects of the movement of the chip during the bonding phase. In other words, the positioning tool 10 according to the invention allows, on the one hand, a large chip to be grasped and held in position along a plane and, on the other hand, a force to be applied onto the chip, at a predefined point of the chip, preferably the centre thereof, so as to bend it at this point. With the chip being fragile, the application of the force is controlled in order to obtain a controlled bend of the chip. The application of the force by the bending device is adapted so as to maintain the curvature of the chip until the chip comes into contact with its support at the desired point. In other words, the bending device can be a simple point contact 21. The bending point of the chip is brought into contact with the support. Once the chip and its support come into contact, the gripping device 14 releases its hold. In other words, it releases the chip, which then returns to its initial flat position and assumes its place on the flat support. The release of the chip can also be controlled, as explained hereafter.

The positioning tool according to the invention has multiple advantages. Such a positioning tool allows any size of chip to be picked and placed, even large chips, with precision within the range of +/−20 μm (micrometres), whilst limiting the effects of offsetting when settling on an adhesive film, whilst guaranteeing the mechanical and electrical integrity of the sensor on which the chip is bonded. Large dimensions are understood to be chips that are bigger than 20 mm×20 mm, for example, 50 mm ×50 mm, 70 mm×110 mm, 100 mm×50 mm, 100 mm×150 mm, even 200 mm×200 mm and more.

Furthermore, as the chip is bent at the bending point, the adhesion of the chip on the sensor occurs from the centre of the chip towards the edge, the effect of which is to limit the creation of bubbles at the interface between the chip and the adhesive film deposited onto the sensor. This allows a hermetic and sealed structure to be obtained more easily. Indeed, the guarantee of bonding from the centre towards the edges provided by the positioning tool according to the invention limits the effects of constrained bonding on the edges, which would make sealed peripheral bonding difficult and even impossible. This last point is associated with the subsequent steps of removing bubbles at the interface requiring continuous and hermetic bonding of the edges of the chip.

FIG. 2 schematically shows an embodiment of the positioning tool 20 according to the invention. In this embodiment, the gripping device 14 comprises at least two suction cups 22, 23, each having a first end 24, 25 connected to the base 13 and a second end 26, 27 located in the gripping plane 15. In FIG. 2, two suction cups 22, 23 are shown. The gripping device 14 can also comprise 3, or advantageously 4, suction cups distributed over the base 13 and advantageously positioned in the vicinity of the edges of the base 13. It can also comprise more than 4 suction cups. The second ends 26, 27 of the suction cups are located in the gripping plane 15. Before the chip is gripped by the positioning tool 20, the chip is positioned on an initial flat support. When the positioning tool 20 picks a chip, there are two scenarios. Either the second end 18 of the bending device 16 is located in the contact plane 15 or is not yet in contact with the contact plane 15, and, in this case, the chip is positioned in the gripping plane, which is substantially parallel to the plane of the support on which the chip is intended to be bonded. The second end 18 of the bending device 16 translationally moves towards the chip until it comes into contact therewith and applies a controlled force, in order to deform the chip at the contact point between the second end 18 and the chip. Or the second end 18 of the bending device 16 is located beyond the contact plane 15, and, in this case, the ends 26, 27 of the suction cups 22, 23 are not yet brought into contact with the chip. As the positioning tool approaches the chip, the end 18 firstly makes contact with the chip, and as the positioning tool approaches, and until the chip is gripped by the suction cups, the bending device 16 contracts due to the reduction in the imposed distance between the base 13 and the chip, and due to the fact that the chip is still positioned on its initial flat support. In other words, the end 18 of the bending device 16 translationally moves relative to the chip along the axis Z, in the opposite direction to the direction of translational movement of the first scenario, the bending device 16 contracts. Once the chip is held by the gripping device 14 (for example, the suction cups 22, 23), the chip can be lifted from its initial flat support. At this stage, the stress is released at the bending device 16, which returns to its initial shape, it relaxes, its end 18 translationally moves towards the chip and deforms it at their contact point. This scenario is encountered, for example, with a fixed device with an offset that is preset by thickness washers. The shape of the base 13, the number and the distribution of the suction cups can be adapted according to the shape and the size of the chip to be handled.

Advantageously, but not necessarily, the bending device 16 is positioned between the at least two suction cups. This allows better distribution of the forces applied onto the chip, equally in terms of holding position in a plane and in terms of the application of force for bending the chip.

In a particularly advantageous embodiment for gripping the chip, the at least two suction cups 22, 23 are connected to a vacuum network 31. The step of gripping the chip will be described hereafter.

The bending device 16 can be a presser finger, a spring, a bellows suction cup, a pressure screw, or a ball joint for conforming to the parallelism of the chip in the gripping plane 15. It can also be a washer assembly for adjusting the height of the bending device 16, i.e. for adjusting the distance between its two ends and thereby translationally moving the second end 18 relative to the first end 17 connected to the base 13.

The at least two suction cups 22, 23 connected to the vacuum network 31 provide the function for gripping the chip. The bending device 16 is not connected to the vacuum network. The end 18 thereof is adjusted in order to be moved through the gripping plane 15 and to be positioned relative to the base 13 at a distance that is greater than the distance between the gripping plane 15 and the base 13.

Advantageously, the at least two suction cups 22, 23 comprise silicon. The dissipative silicon suction cups limit the risks of indenting layers and of damages associated with electrostatic discharges.

The use of commercial suction cups is perfectly suitable for implementing the positioning tool 20 according to the invention. The use of standard consumables (suction cups) facilitates supply and allows reasonable prices to be guaranteed for regular supplies. This also allows a selection of hardnesses and electrical features for the suction cups to be provided, in particular for the dissipative aspect for limiting the risks associated with the electrostatic charges.

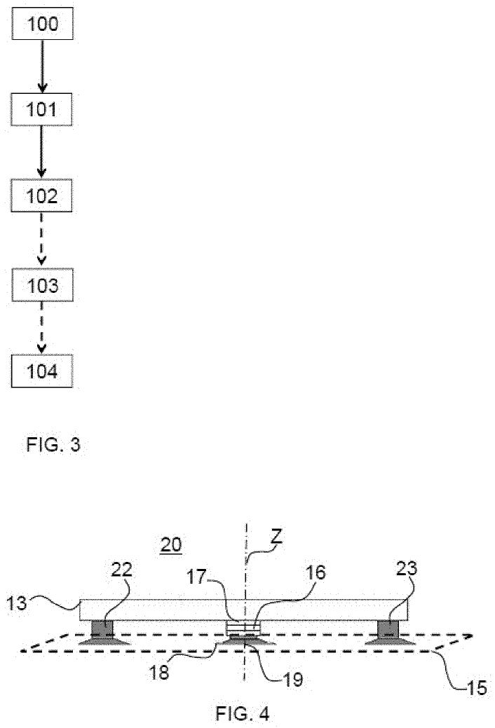

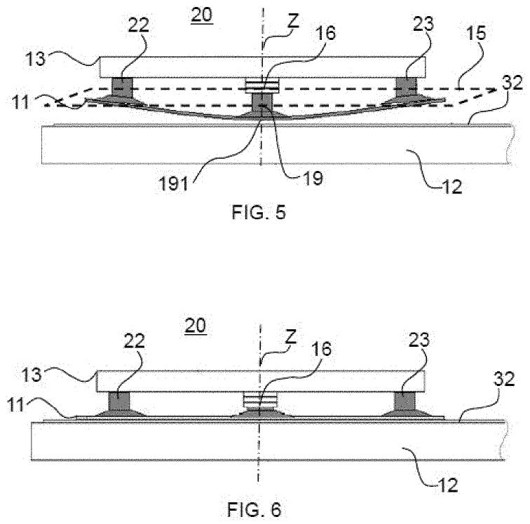

FIG. 3 schematically shows the steps of the method for positioning a flat wafer on a flat support according to the invention. The method for positioning a flat wafer 11 (large chip) on a flat support 12 (sensor) comprises the following steps. Firstly, there is a step 100 of gripping the flat wafer 11 using a gripping device 14. During this step, the chip is grasped by the positioning tool 20, more specifically by the gripping device 14, and is positioned in the gripping plane. Subsequently, there is a step 101 of holding the flat wafer 11 in the gripping plane 15. Finally, the method according to the invention comprises a step 102 of bending the flat wafer 11 through translational movement along a first intersecting axis Z, which is preferably substantially perpendicular, from a second end 18 of a bending device 16 through the gripping plane 15 at a contact point 19, so as to form a bending point 191 of the flat wafer 11. The flat wafer 11 is then curved at a bending point 191, as shown in FIG. 5. Advantageously, the bending step 102 occurs after the gripping step 100 and the holding step 101. However, it is also possible to contemplate, in particular in the case where the suction cups are connected to the vacuum network, bending (step 102) the flat wafer at the same time as the gripping step and the holding step.

The positioning method can comprise, after the step 102 of bending the flat wafer 11, a step 103 of bringing the bending point 191 of the curved flat wafer 11 into contact with the flat support 12. Finally, the positioning method can comprise, after the contact step 103, a step 104 of releasing the flat wafer 11 onto the flat support 12. At this stage, the chip 11 is bonded onto the sensor 12 with the desired precision (of several micrometres), without forming bubbles in the adhesive. A step 104 of releasing the flat wafer 11 onto the flat support 12 then occurs, during which step the positioning tool disconnects from the flat wafer 11, which is then bonded onto its support.

FIG. 4 schematically shows the positioning tool 20 according to the invention during the step 100 of gripping the chip 11 using a gripping device 14. In this figure, the chip 11 is not shown but it can be assimilated with the gripping plane 15, in which it is positioned after having been grasped by the tool. Two suction cups can be seen, but it is also perfectly possible to have more, for example, four positioned in the vicinity of the four corners of the base 13, and the bending device 16 is then positioned at the centre of the four suction cups. In the event that the gripping device 14 comprises suction cups connected to the vacuum network 31, the suction cups approach the flat surface of the chip 11. The suction cups 22, 23 are placed in a vacuum, which sucks the chip pushed back by the atmospheric pressure. The suction cups and the chip are thus held together and the chip is positioned in the gripping plane 15 defined by the second ends of the suction cups. At this stage of the method, the chip 11 is held in the gripping plane 15.

FIG. 5 schematically shows the positioning tool 20 according to the invention during the step 102 of bending the chip 11. The gripping device 14 holds the chip, which is secured to the positioning tool 20. During the bending step 102, the second end 18 of the bending device 16, for example, a presser finger, translationally moves along the axis Z towards the gripping plane 15, until it comes into contact with the gripping plane 15 at the contact point 19 (first scenario described previously) or translationally moves along the axis Z towards the base 13 by contracting (second scenario described previously). After gripping the chip, and when the chip is lifted from its initial flat support, the second end 18 applies a force onto the chip 11 at the contact point 19. At the contact point 19, the chip 11 bends. The chip 11 is not completely in the gripping plane 15 due to the curvature of the chip 11, which then has a bending point 191.

It is to be noted that the deformation of the chip is shown in an exaggerated manner in order to illustrate the principle. The assembly of the suction cups of the gripping device 15 and of the bending device 16 is advantageously carried out so as to allow a lower position of several hundred microns for the bending device 16, relative to the gripping plane 15. The deformation of a chip 11 with a thickness of the order of 400 micrometres is of the order of 100 micrometres. This makes it possible to avoid settling the chip 11 on the adhesive film 32 on an edge or a corner, whilst guaranteeing settling on the central zone. The necessary force that does not exceed several hundred grams allows the surface layers of the flat wafer (chip 11) to be preserved.

FIG. 6 schematically shows the positioning tool 20 according to the invention after the step 103 of bringing the chip 11 into contact on its support 12. The positioning tool 20 approaches the support 12 until the bending point 191 of the chip comes into contact on the support. By virtue of the curvature of the chip 11, it is easy to position this point at the desired location on the support. There is no risk of an edge effect that would make an edge or a corner touch the adhesive film 32 on the support 12. After the step 103 of bringing the chip 11 into contact on the support 12, the chip 11 is released onto the flat support 12. This step also can be denoted depositing step. The gripping device 14 releases the chip 11, which is then in place on its support, and the positioning tool 20 is disconnected from the chip 11. In the event that the gripping device 14 comprises suction cups connected to the vacuum network 31, the step 104 of releasing the chip corresponds to the end of suction, in which the vacuum is broken in order to release the chip 11. As can be seen in FIG. 6, the chip 11 is again flat. The gripping device 14 no longer holds the chip 11 and, as the bending device 16 does not apply any force onto the chip 11, except for the force along the axis Z for bending it so that it can be positioned on the flat support 12, the positioning tool can be used to grip and position another chip 11.

The solution provided is therefore based on gripping and holding a chip in a gripping plane 15 and on bending this chip to allow the bending point of the chip to settle on the flat support sensor. This solution allows the effects of movement of the chip to be limited during the phase of adhering onto the flat support sensor.

The adhesion of the chip therefore occurs from the centre of the chip towards its edges. This consequently limits the creation of bubbles at the interface between the chip and the flat support. The advantage that is derived from the absence of bubbles, or at least from the limitation of the creation of bubbles, is that of obtaining a hermetic and sealed structure.

Advantageously, the gripping device comprises a plurality of coplanar suction cups providing the function for gripping the chip, and the bending device has a second end that is not coplanar with the suction cups of the gripping device, which gripping device is configured to provide the function for controlled bending of the chip.

The invention is preferably applicable, but by no means limited to, picking and placing silicon chips that are bigger than 20 mm×20 mm onto an adhesive film. By extension, the invention is applicable to any method for picking and placing flat wafers that can be deformed, even slightly, under stress, with significant constraints with respect to the positioning tolerance and the lack of bubbles in the adhesive at the interface between the flat wafer and the support on which the flat wafer is intended to be placed.

1. A positioning tool able to position a flat wafer on a flat support, comprising:
a. a base;
b. a gripping device connected to the base, defining a gripping plane, the gripping device being able to grasp a first surface of the flat wafer and hold it in the gripping plane;
c. a bending device, having a first end connected to the base and a second end translationally movable along a first intersecting axis Z, which is preferably substantially perpendicular, through the gripping plane at a contact point, the bending device being configured to apply a force onto the first surface of the flat wafer at a bending point, so as to bend the flat wafer at this bending point.

2. The positioning tool according to claim 1, wherein the bending device is a point contact.

3. The positioning tool according to claim 1, wherein the gripping device comprises at least two suction cups, each having a first end connected to the base and a second end located in the gripping plane.

4. The positioning tool according to claim 3, wherein the bending device is positioned between the at least two suction cups.

5. The positioning tool according to claim 3, wherein the at least two suction cups are connected to a vacuum network.

6. The positioning tool according to claim 3, wherein the at least two suction cups comprise silicon.

7. The positioning tool according to claim 1, wherein the bending device is a presser finger, a spring, a bellows suction cup, a pressure screw, or a ball joint.

8. A method for positioning a flat wafer on a flat support, comprising the following steps:
a. gripping a first surface of the flat wafer using a gripping device;
b. holding the flat wafer in a gripping plane;
c. bending the flat wafer through translational movement along a first intersecting axis Z, which is preferably substantially perpendicular, from a second end of a bending device through the gripping plane at a contact point and applying a force onto the first surface of the flat wafer at a bending point, so as to bend the flat wafer at this bending point of the flat wafer.

9. The positioning method according to claim 8, comprising after the step of bending the flat wafer, a step of bringing the bending point of the curved flat wafer into contact with the flat support.

10. The positioning method according to claim 9, comprising after the contact step, a step of releasing the flat wafer onto the flat support.
